(19) United States
(12) Patent Application Publication
(10) Pub. No.: US 2026/0372030 A1
(43) Pub. Date: Nov. 19, 2026

(54) DONOR WAFER SUITABLE FOR THE PRODUCTION OF ENGINEERED SUBSTRATES

(71) Applicant: IMEC VZW, Leuven (BE)

(72) Inventors: Bernardette Kunert, Gemmenich (BE); Nadine Collaert, Blanden (BE); Abhitosh Vais, Heverlee (BE); Reynald Alcotte, Bruxelles (BE); Guillaume Boccardi, Sint-Lambrechts-Woluwe (BE); Yves Mols, Wijnegem (BE); Sachin Yadav, Leuven (BE); Annie Kumar, Leuven (BE); Bertrand Parvais, Nil-Saint-Vincent (BE); Francois Chancerel, Bruxelles (BE); Robert Miller, Lubbeek (BE)

(21) Appl. No.: 19/675,467

(22) Filed: May 12, 2026

(30) Foreign Application Priority Data
May 13, 2025 (EP) 25176098.9

(51) Int. Cl. H10P 95/00; C30B 25/18; C30B 29/40; C30B 31/22; H10P 14/20

(52) U.S. Cl. CPC H10P 95/112; C30B 25/18; C30B 29/40; C30B 31/22; H10P 14/271; H10P 14/2905; H10P 14/2925; H10P 14/3414

(57) ABSTRACT

A donor wafer includes a support substrate formed of a first crystalline semiconductor material, a template layer on the support substrate, and a plurality of structures disposed in trenches extending through the template layer and formed of a second crystalline semiconductor material. Each structure has a planar bonding surface, and the planar bonding surfaces of the structures are coplanar. An upper surface of the template layer is recessed relative to the planar bonding surfaces such that stripe portions of the structures extend outward from the recessed upper surface of the template layer. Each structure includes a release layer positioned to transfer at least an upper part of the stripe portions to a carrier substrate. The donor wafer is produced by growing the structures in the trenches in a manner that provides for aspect ratio trapping of threading dislocations, thereby improving crystal quality in the stripe portions to be transferred.

### CROSS-REFERENCE TO RELATED APPLICATION(S)

The present application is a non-provisional patent application claiming priority to European Patent Application No. 25176098.9, filed May 13, 2025, the contents of which are hereby incorporated by reference.

### FIELD OF THE DISCLOSURE

The present disclosure is related to semiconductor processing, including the manufacturing and use of engineered substrates.

### BACKGROUND

Engineered substrates in semiconductor fabrication may be substrates composed of a carrier substrate and a crystalline semiconductor layer bonded thereto and suitable as a seed layer for epitaxial growth of additional layers for the fabrication of semiconductor devices. Various types of engineered substrates are known, for example, comprising a III-V semiconductor layer bonded to a crystalline Si substrate, a polycrystalline Si substrate, a polycrystalline AlN substrate, or a polycrystalline SiC substrate.

The application of engineered substrates is useful for integrating III-V devices onto large-diameter substrates, including Si substrates, but not limited thereto. For example, III-V device fabrication on 200/300 mm large-diameter Si wafers provide access to mature Si foundries and reduces production costs. Additionally, III-V devices with Si-based functionalities may be co-integrated using large-diameter Silicon photonic or CMOS wafers, optionally via wafer-to-wafer bonding.

Engineered substrates may be produced, for example, by bonding a bulk III-V substrate to the handle wafer and thereafter splitting a thin layer of III-V material from the bulk III-V substrate using a preliminary ion implantation performed in the bulk III-V substrate. This method, trademarked as SMART CUT™ by Soitec, transfers Si layers onto large-diameter SiO₂/Si wafers to produce silicon-on-insulator (SOI) substrates, as well as transfers InP layers from a 100 mm diameter InP bulk wafer to Si, for example. Larger InP-on-Si substrates, often referred to as InPOSi substrates, can be produced using the same SMART CUT™ method after bonding multiple InP tiles to a large Si handle wafer, for example, 200 mm or 300 mm in diameter.

The fabrication of crystalline bulk wafers of III-V or similar semiconductor materials is, however, associated with high manufacturing costs (e.g., expensive), and therefore it would be useful to have more sustainable methods of fabricating engineered substrates.

### SUMMARY

The present disclosure provides an improved type of donor wafer that can be applied in the manufacturing of engineered substrates, for example, substrates composed of a carrier substrate and a crystalline semiconductor layer bonded thereto and suitable as a seed layer for epitaxial growth of additional layers (e.g., required) for the fabrication of semiconductor devices. In accordance with the appended claims, the present disclosure is related to the donor wafer as such, to methods of fabricating the donor wafer and of re-using the donor wafer after a first or subsequent use, and to methods of producing an engineered substrate using a donor wafer according to the present disclosure.

A donor wafer, according to the present disclosure, comprises structures embedded in trenches formed in a template layer that lies on top of a support substrate formed of a first crystalline semiconductor material. According to example embodiments of the present disclosure, a template layer refers to a layer including trenches extending through the entire (e.g., full) thickness of the template layer. The template layer may be formed of a material or materials different from the support substrate and provides (e.g., enables) selective area growth of a second semiconductor material from a bottom of the trench upwards (e.g., the second material grows on the first material rather than on the material of the template layer). The structures comprise a planar bonding surface, with (e.g., all) the bonding surfaces of the structures being coplanar. An upper surface of the template layer may be recessed relative to the bonding surfaces such that stripe portions of the structures extend outward from the recessed upper surface of the template layer. The structures comprise a release layer positioned between a bulk portion of the structures and at least an upper part of the stripes. The release layer may bond the structures to a carrier substrate and release the release layer to thereby transfer the at least upper part of the stripe portions to the carrier substrate. The donor wafer may be produced by growing the material of the structures in a manner that may confine and trap threading dislocations so that the structures exhibit high crystal quality in the transferred part of the stripe portions. The high (e.g., crystal) quality can be quantified by upper limit values of the threading dislocation density (TDD) measured on the planar bonding surfaces of the structures before transfer.

A donor wafer according to the present disclosure may be formed without (e.g., requiring) a bulk wafer formed of the donor material.

The present disclosure provides a donor wafer for the production of engineered semiconductor substrates. The donor wafer includes a support substrate formed of a first crystalline semiconductor material, a template layer on the support substrate, the template layer comprising a plurality of trenches, through the entire (e.g., full) thickness of the template layer, and a plurality of structures respectively disposed in the trenches, and formed of a second crystalline semiconductor material. Each structure of the plurality of structures comprises a planar bonding surface, with (e.g., all) the bonding surfaces of the structures being coplanar. The upper surface of the template layer may be recessed relative to the bonding surfaces, so that stripe portions of the structures extend outward from the recessed upper surface of the template layer. Each structure of the plurality of structures comprises a release layer positioned to transfer (e.g., enable transferring) at least an upper part of the stripe portions to a carrier substrate.

According to an example embodiment, the trenches comprise a base portion and an upper portion, the upper portion being wider than the base portion.

According to an example embodiment, the aspect ratio of each of the base portion and the upper portion of the trenches may be equal to or greater than 2.

According to an example embodiment, the height of the stripe portions may be between 10 nm and 1 μm.

According to an example embodiment, the first semiconductor material may be silicon and the second semiconductor material may be a group III-V or group IV semiconductor material.

According to an example embodiment, the width of the stripe portions of the structures is between 0.5 μm and 20 μm.

According to an example embodiment, the threading dislocation density measured on the planar bonding surfaces of the structures is lower than 5E8 cm⁻².

According to an example embodiment, the threading dislocation density measured on the planar bonding surfaces of the structures is lower than 1E7 cm⁻².

The present disclosure also provides a method for producing a donor wafer according to the present disclosure. The method comprising (e.g., the steps of) providing a support substrate formed of the first crystalline semiconductor material, and forming the template layer on the support substrate. The template layer comprises a plurality of trenches through the entire (e.g., full) thickness of the template layer. The trenches have a base portion and an upper portion. The upper surface of the support substrate may be exposed at the bottom of the base portion of the trenches, and the upper portion of the trenches may be wider than the base portion. By epitaxial growth, the structures formed of the second semiconductor material may be grown upward from the bottom of the base portions of the trenches., The structures may grow upward and outward (e.g., out) of the base portions so as to become embedded in the upper portions of the trenches. The crystal orientation and shape of the bottom of the base portions and the aspect ratio of the base portions are configured to enable aspect ratio trapping of threading dislocations in the base portions. Further, the epitaxial growth may be continued until the structures extend outward from the upper portions of the trenches. Further, the method may include (e.g., thereafter) performing a planarization, thereby making the upper surfaces of the structures and of the template layer coplanar, and thereby creating the coplanar bonding surfaces of the structures. Further, the method may include (e.g., thereafter) recessing the template layer relative to the structures to create the stripe portions extending outward from the recessed template layer, and implanting ions in the structures, to (e.g., thereby) create the release layer.

According to an example embodiment, the method for producing the donor wafer further comprises (e.g., the step of) forming a dielectric bonding layer conformally on the topography provided (e.g., defined) by the stripe portions and the surface of the recessed template layer.

According to an example embodiment, the implanting step may be performed after the step of forming the dielectric bonding layer. According to another example embodiment, the implanting step may be performed before the step of forming the dielectric bonding layer.

The present disclosure also relates to a method for producing an engineered substrate using a donor wafer according to the present disclosure. The method comprising (e.g., the steps of) if the donor wafer does not already comprise a dielectric bonding layer formed conformally on the topography provided (e.g., defined) by the stripe portions and the surface of the recessed template layer, producing the dielectric bonding layer on the topography, bonding the donor wafer to a carrier substrate by bonding the dielectric bonding layer to the carrier substrate, (e.g., thereafter) releasing the release layer to thereby transfer at least an upper part of the stripe portions of the structures to the carrier substrate, depositing a dielectric material on the carrier substrate, thereby filling the spaces between the transferred parts of the stripe portions, and performing planarization, making the surface of the transferred parts of the stripe portions coplanar with the dielectric material, thereby obtaining the engineered substrate.

The present disclosure also provides a method for preparing a donor wafer according to the present disclosure for re-use, after a first or subsequent use of the donor wafer in the production of an engineered substrate by a method according to the present disclosure. The method comprising planarizing the donor wafer, thereby making the upper surfaces of the structures and of the template layer or the bonding layer coplanar, recessing the template layer and/or the bonding layer relative to the structures, to obtain again stripe portions of the structures extending outward from the recessed upper surface of the template layer, implanting ions in the structures to create again a release layer.

The present disclosure also provides a method for preparing a donor wafer according to the present disclosure for re-use, after a first or subsequent use of the donor wafer in the production of an engineered substrate by a method according to the present disclosure. The method comprising, by selective epitaxial growth, growing the second semiconductor material on the released structures to thereby obtain again stripe portions of the structures, extending outward from the recessed template layer, implanting ions in the structures to create again a release layer.

### BRIEF DESCRIPTION OF THE FIGURES

The above, as well as additional, features will be better understood through the following illustrative and non-limiting detailed description of example embodiments, with reference to the appended drawings.

FIGS. 1, 2, 3, 4, 5, 6, 7, 8, 9, 10, and 11 illustrate a method according to an example embodiment of the present disclosure, for producing a donor wafer.

FIGS. 12, 13, and 14 illustrate a method for producing an engineered substrate with the use of the donor wafer, which may be produced by the method illustrated in FIGS. 1-9, according to an example embodiment of the present disclosure.

FIGS. 15, 16, and 17 illustrate different methods of re-using the donor wafer, according to an example embodiment of the present disclosure.

All the figures are schematic, not necessarily to scale, and generally only show parts which are necessary to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

A number of (e.g., example) embodiments will be described in detail. Any reference to dimensions or materials are provided as examples and does not limit the scope of the present disclosure.

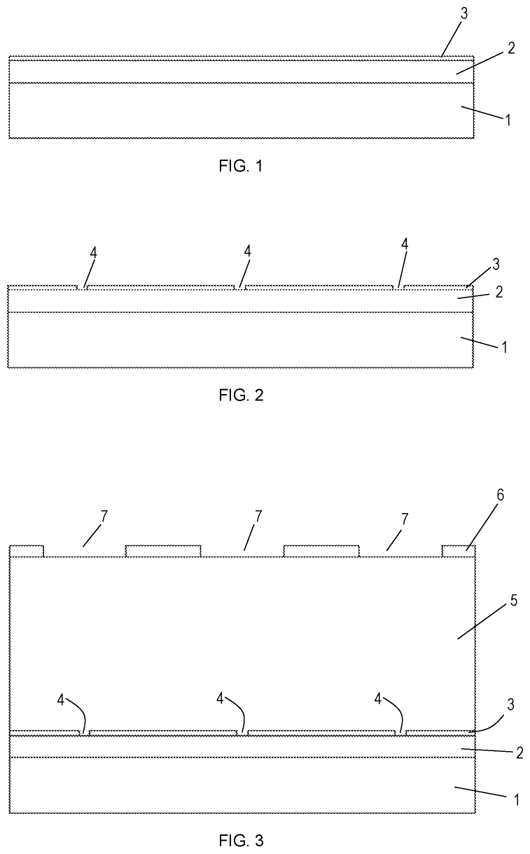

First a method for producing a donor wafer according to an example embodiment is described. With reference to FIG. 1, a crystalline silicon wafer 1 is provided. This may be a standard Si process wafer of several hundred micrometers in thickness and up to 300 mm in diameter. The image in FIG. 1 shows (e.g., only) a thin upper portion of the wafer 1 in a section (e.g., cross-section) view of a small wafer segment.

On the front side of the wafer 1, a stack of a first layer 2 and a second layer 3 is produced. The first layer 2 may be formed of a dielectric material, for example silicon oxide (SiO₂), and can be produced by thermal oxidation or by a deposition technique, such as Chemical Vapor Deposition (CVD). The first layer 2 may be about 0.6 μm thick. The second layer 3 may be less than 0.2 μm thick and may serve as a mask layer. The material of this layer may be for example silicon nitride (SiN), amorphous Si or aluminium oxide (Al₂O₃), applied by a (e.g., conventional) method for producing a layer of these materials.

On the back side of the wafer 1 (not shown), a stress compensation layer may be produced. This could be a layer of silicon oxide or silicon nitride with an adjusted strain state for compensating strain caused by the layers produced on the front side. The strain compensation layer may have a thickness and may be provided with material specifications (e.g., requirements).

The mask layer 3 is patterned as shown in FIG. 2, forming narrow elongated openings 4 (e.g., therein), which can be realized by conventional lithography and etching techniques. The width of the openings 4 is about 0.3μm. In the length direction, the openings 4 may extend in the order of hundreds of micrometers or in the order of millimeters.

With reference to FIG. 3, a second dielectric layer 5 is formed to have a thickness of about 5.4 μm, followed by a further mask layer 6 that is (e.g., subsequently) patterned to form wider elongated openings 7 aligned to the narrow openings 4. The further mask layer 6 may be formed of the same material as the first mask layer, or from another material suitable for the same purpose. The wider openings 7 are (e.g., essentially or substantially) concentric with the narrower openings 4. The term “essentially” allows some deviation that falls within the overlay accuracy of the lithographic process applied for patterning the further mask layer 6. The second dielectric layer 5 may also be a layer of silicon oxide, produced for example by CVD.

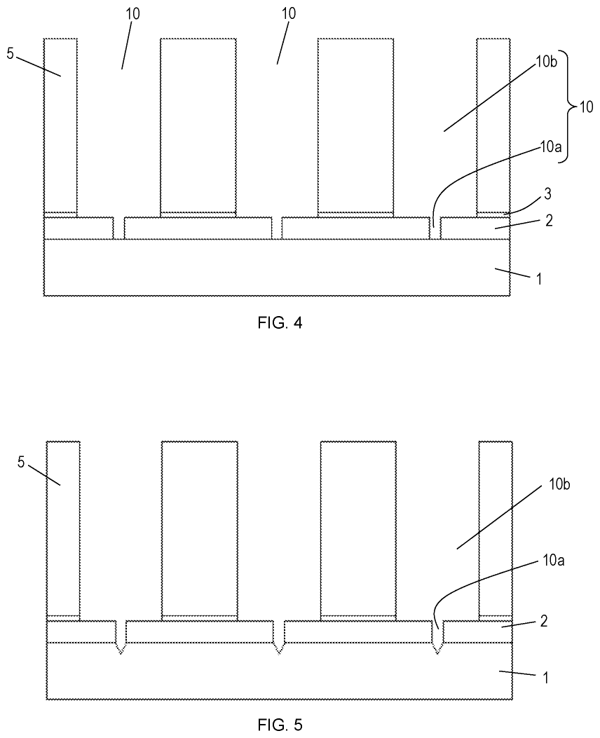

With reference to FIG. 4, the pattern of wider openings 7 is transferred to the second dielectric layer 5 by anisotropic etching. Thereafter, the narrower openings 4 are transferred to the first dielectric layer 2. In FIG. 4, no mask material remains on the horizontal surfaces exposed to the anisotropic etch species applied for transferring the openings. In an example embodiment, the mask layers may be consumed during the anisotropic etch processes and thus removed from the horizontal surfaces. In another example embodiment, some of the mask material remains and is stripped after the transfer of the openings. If mask material remains however, the mask material may be left in place and may proceed with the method as described hereinafter.

Transferring the openings 4 and 7 may result in parallel trenches 10 formed through the stack of layers 2, 3, 5, the trenches having a narrow base portion 10a and a wider upper portion 10b.

In the example embodiment shown, the width of the narrow base portion 10a is about 0.3 μm, and the height of the narrow base portion is about 0.6 μm. The width of the upper portion 10b is about 2.5 μm, while the height of the upper portion is about 5.4 μm. The aspect ratio of both the base and the upper portion is about 2. According to other example embodiments, the width of the base portion 10a may be between 0.1 μm and 0.5 μm, while the height of the base portion may be between 0.2 μm and 2 μm. The width of the upper portion 10b may be between 0.5 μm and 20 μm, while the height of the upper portion may be between 1 μm and 40 μm. For example, the aspect ratio of the base portion 10a may be equal to or greater than 2. According to further example embodiments, the aspect ratio of the upper portion 10b of the trenches may also be equal to or greater than 2. In some example embodiments, the trenches 10 have substantially the same dimensions and are arranged at regular spacings from each other, although the present disclosure is not limited to such example embodiments.

The image shows (e.g., only) a small portion of the wafer 1 comprising three trenches 10, which are part of an array of a larger number of (e.g., equally spaced) parallel trenches. The length of the trenches may be in the order of hundreds of micrometers or in the order of millimeters. The arrays of trenches may be arranged (e.g., in any manner) on the wafer 1. However, in some example embodiments, the arrays of trenches 10 may be oriented along two orthogonal directions on the wafer, with about equal numbers of trenches oriented in both directions.

As seen in FIG. 4, at the bottom of the base portion 10a of the trenches, the surface of the Si wafer 1 is exposed. As illustrated in FIG. 5, the wafer is subjected to an etching step wherein the bottom of the trenches is etched, forming a V-shaped bottom. The etching may be a wet etching process, when the Si wafer 1 is a (100) oriented Si substrate and the trenches are oriented along <011>. The inclined surfaces are then provided (e.g., defined) by the {111} Si crystal facets.

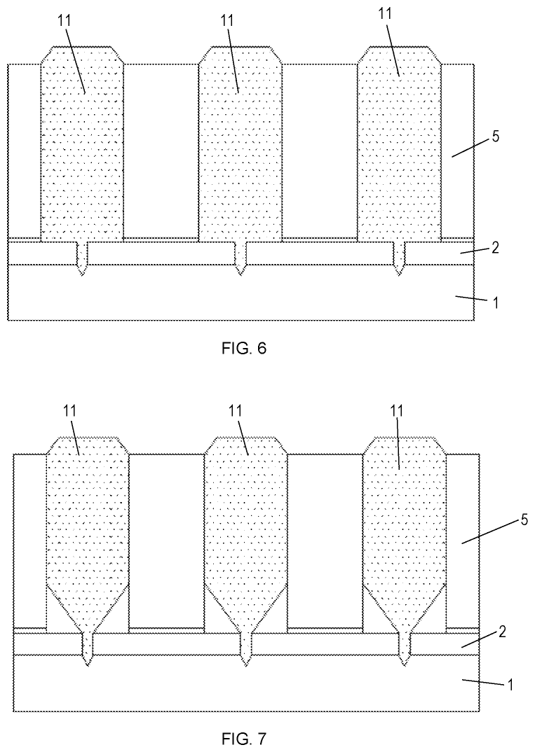

Thereafter, a layer is grown selectively by epitaxial growth on the exposed silicon surface at the bottom of the trenches. In the example embodiment shown, this may be a layer of III-V semiconductor material that exhibits a significant lattice mismatch and thermal expansion coefficient mismatch compared to crystalline silicon. The material may, for example, be grown by metal organic vapor phase epitaxy (MOVPE), applying conventional parameters and tools. The material grows selectively on the Si and not on the SiO₂. Applying (e.g., optimized) growth conditions which enhance strain relaxation along the inclined growth surface and thread (e.g., enable efficient threading) dislocation gliding, due to the high aspect ratio of the base portion 10a of the trenches, threading dislocations are confined and trapped in the base portion 10a, and high quality III-V material (e.g., material exhibiting low threading dislocation density) grows out of the base portions 10a and becomes embedded in the upper portions 10b of the trenches formed in the stack of layers 2,3,5, which is hereafter referred to as a template layer. As shown in FIG. 6, epitaxial growth results in the formation of structures 11 embedded in the trenches 10 and exhibit low threading dislocation density in an upper region of the structures. Example upper limit values of the density will be provided further below. When the upper portion 10b exhibits a high aspect ratio, for example, greater than 2, this high aspect ratio provides an additional defect trapping effect in case not all defects are confined in the base portion 10a.

The growth of the structures 11 can be more readily understood from document EP 3789519A1, where for example details and examples of parameters and tools may be found. The manner in which the material grows out of the base portion 10a of the trenches may depend on the material and on (e.g., specific) growth parameters. Some materials fill the upper portion 10b of the trenches completely, as shown in FIG. 6, while others exhibit faceted growth with a specific shape defined by the facet, as illustrated in FIG. 7 in the case of a {111} facet. Both options are possible within the scope of the present disclosure.

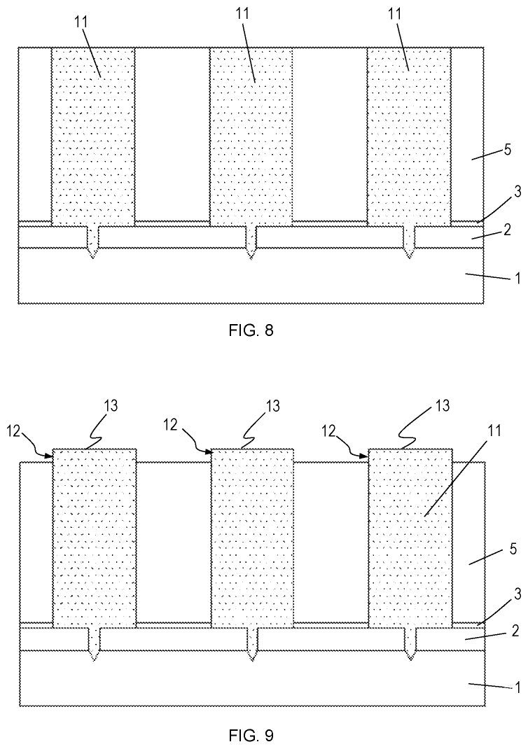

The growth of the structures 11 continues until the structures extend outward from the upper portion of the trenches 10. Thereafter, a planarization is applied, as illustrated in FIG. 8. The upper surfaces of the structures 11 are planarized to a common level with the upper surface of the template layer 2,3,5. Planarization as applied within the present description may apply a method for rendering an uneven surface planar, such as grinding or polishing, including CMP techniques (Chemical Mechanical Polishing).

Thereafter, the template layer 2, 3, 5 is recessed (e.g., etched back relative to the structures 11) by a selective etch process, as illustrated in FIG. 9. The structures 11 may now extend outward from the recessed surface of the template layer 2,3,5, forming parallel stripe portions 12 (hereafter also referred to as “stripes”). The height of the stripes 12 (e.g., the distance between the recessed surface of the template layer 2, 3, 5 and the planar upper surface of the structures 11) may be in the order of a few hundred nanometers. For example, the height of the strips 12 may be between 10 nm and 1 micrometer. The planarized surfaces 13 of the structures 11 (and of the stripes 12) are referred to as bonding surfaces, as these surfaces are to be bonded to a carrier wafer in a process for producing an engineered substrate (as described further herein). In an example embodiment, the bonding surfaces 13 of the structures 11 are (e.g., all) coplanar.

On the donor wafer as shown in FIG. 9, the high crystal quality in an upper region of the structures 11 can be expressed in terms of the threading dislocation density (TDD) as measured on the bonding surfaces 13 of the structures 11. Example upper limit values of the TDD may differ depending on the material of the structures 11. For example, for grown structures 11 formed of group-IV alloys or III-V semiconductors having a zinc blende crystal structure (e.g. GaAs, InP, GaSb, InAs), the TDD measured on the bonding surfaces 13 may be lower than 1E7 cm⁻². For III-V semiconductors having a wurtzite crystal structure (e.g. GaN), the TDD measured on the bonding surfaces 13 may be below 5E8 cm⁻².

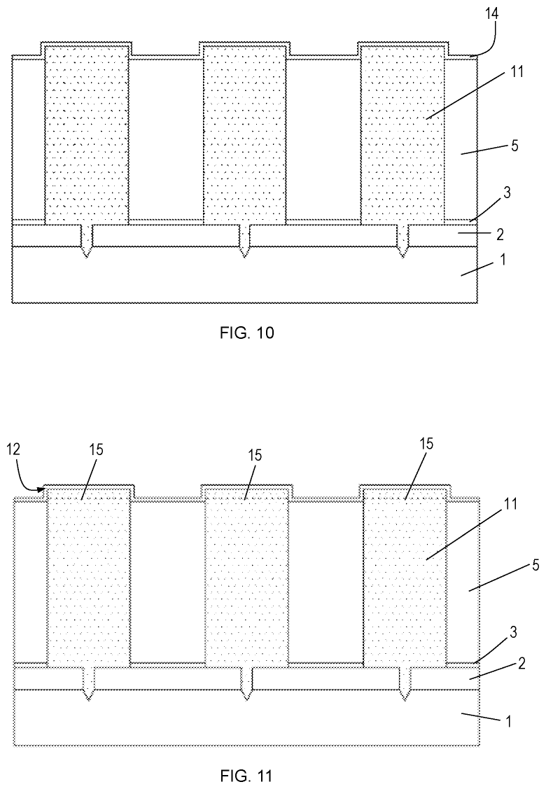

Then, with reference to FIG. 10, a bonding layer 14 is produced conformally on the recessed surface of the template layer 2, 3, 5 and on the stripes 12. For example, the bonding layer 14 follows the topography provided (e.g., defined) by the stripes 12 and the recessed surface. The bonding layer 14 may be a dielectric layer (e.g., suitable) for direct dielectric-to-dielectric bonding techniques, for example a layer formed of SiCN, SiO₂, SiC, Al₂O₃ or AlN.

This is followed by an ion implantation step illustrated in FIG. 11, which may be performed in accordance with the similar practice of implanting ions in a bulk III-V wafer in order to perform the SMART CUT™ method. A thin layer of ions is implanted through the planar bonding surfaces of the stripes 12, forming a buried release layer 15. The release layer provides (e.g., defines) an interface between an upper part of the stripes 12 and the bulk of the structures 11. The depth of the implanted layer 15 from the planar surface of the structures 11 is close to but less than the height of the stripes 12. In an alternative example embodiment, the ion implantation is performed before producing the bonding layer 14. In another alternative example embodiment, the ion implantation is performed after planarizing the structures 11 and before recessing the surface of the template layer 2, 3, 5.

A donor wafer according to the present disclosure is thus characterized by the presence of the structures 11 embedded in trenches 10 formed in a template layer 2, 3, 5 that lies on top of a support substrate 1. The support substrate 1 and the structures 11 are formed of different semiconductor materials. The material of the structures 11 exhibits low threading dislocation density in an upper region of the structures 11. The structures 11 comprise a planar bonding surface 13, with (e.g., all) the bonding surfaces of the structures being coplanar. The surface of the template layer 2, 3, 5 is recessed relative to the bonding surfaces 13, so that stripe portions 12 of the structures extend outward from the recessed template layer 2,3,5. The structures comprise a release layer 15 that bonds (e.g., enables bonding) the structures to a carrier substrate and releases the release layer to thereby transfer at least an upper part of the stripe portions 12 to the carrier substrate. The donor wafer may further comprise a bonding layer 14.

A donor wafer according to the present disclosure may be provided without (e.g., requiring) a bulk wafer of the transferred material. The material is grown on the donor wafer, and the donor wafer's structure, comprising proliferated stripes extending outward from a recessed template layer, provides for (e.g., enables) multiple re-uses, as described herein.

In the example embodiment described hereabove and illustrated in the drawings, the manner in which the template layer is produced is different from the approach disclosed in EP 3789519A1. In the latter disclosure, the so-called shallow trench isolation (STI) method is applied for isolating narrow fin-shaped portions of silicon between oxide regions. The fin shaped portions are etched back in order to create the high-aspect ratio trenches (e.g., required) for trapping the threading dislocations.

The use of STI for producing a donor wafer in accordance with the present disclosure is not excluded from the present disclosure scope. However, in the above-described method illustrated in the drawings, STI is not applied. Instead, a layer stack is patterned to form the template layer 2, 3, 5. This provides for (e.g., enables) larger dimensions of the trench widths, so that the width of the upper portions of the structures 11 can be higher compared to structures obtained using STI. This width can be between 0.5 μm and 20 μm according to example embodiments of the present disclosure. A (e.g., significant) portion of the donor wafer surface can be transferred in a process for producing engineered substrates.

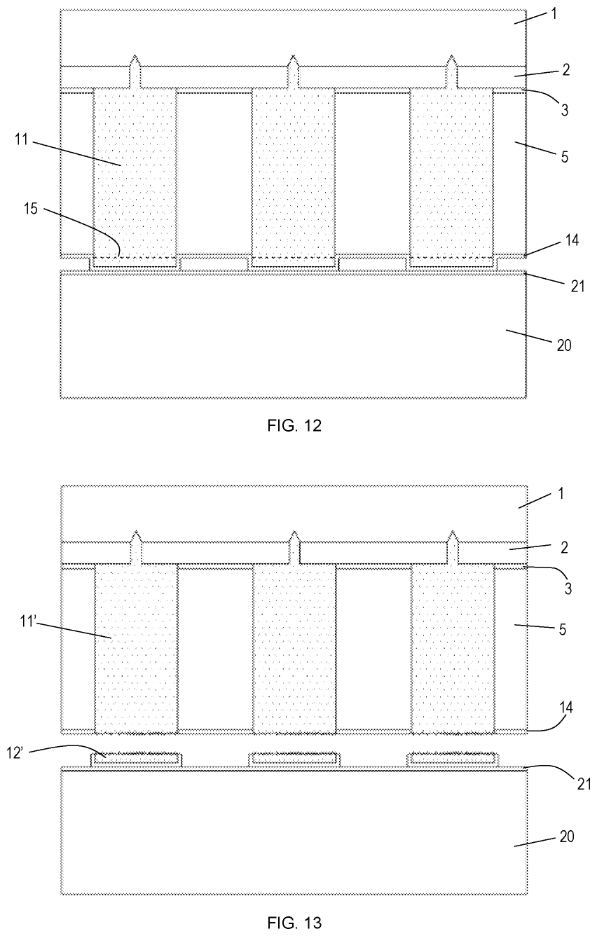

Such a process for producing an engineered substrate using the donor wafer as shown in FIG. 11 is illustrated in FIGS. 12 to 14. A Si carrier wafer 20 is provided which may be a process wafer of the same diameter as the donor wafer. The carrier wafer 20 is provided with a dielectric bonding layer 21 on its surface, which may be formed of the same material as the bonding layer 14 formed on the donor wafer. As shown in FIG. 12, the donor wafer is aligned to the carrier wafer 20 and bonded thereto by a known direct dielectric-to-dielectric bonding method.

Thereafter, the assembly of the carrier wafer 20 and the bonded donor wafer is subjected to split annealing (e.g., temperature is raised to a given level suitable for releasing the donor wafer at the interface defined by the implanted ion layer 15), as illustrated in FIG. 13.

The result is the transfer of a portion 12′ of the stripes 12 to the carrier wafer, while bulk portions 11′ of the structures 11 remain embedded in the template layer 2, 3, 5. The position of the release layer 15 is such that at least an upper part 12′ of the stripes 12 is transferred. As illustrated, the release layer 15 may be positioned such that the stripes 12 are substantially fully transferred, for example, the thickness of the transferred portions 12′ is substantially equal or very close to the thickness of the stripes 12 before (e.g., prior to) transfer.

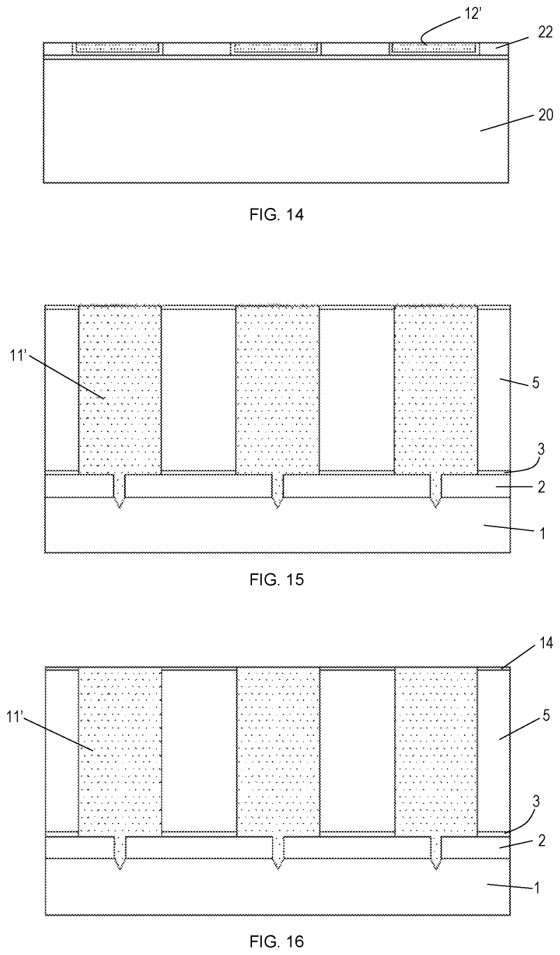

Thereafter, a dielectric material 22 is deposited on the carrier wafer 20, filling the spaces between the transferred stripe portions 12′ and covering the stripe portions, followed by a planarization until the stripe portions 12′ are exposed and coplanar with the dielectric 22, as illustrated in FIG. 14.

After the split annealing, the surfaces of the stripe portions 12′ and of the remaining bulk structures 11′ exhibit high roughness. On the carrier wafer 20, this roughness is reduced by the planarization step which brings the upper surfaces of the planarized stripes 12′ to the same level as the dielectric 22, thereby completing the fabrication of the engineered substrate comprising a carrier wafer 20 and high-quality material of the structures 11, which can for example be a III-V material available on the surface of the engineered substrate in the form of the parallel stripes 12′. Threading dislocation density as measured in the surfaces of the planarized strips 12′ may, for example, be below 1E7 cm⁻² for III-V material. The engineered substrate can be used as a process wafer applicable in Si-based fabrication technology.

After the transfer of the stripe portions 12', the donor wafer can be re-used. A number of different possibilities are available. According to an example embodiment illustrated in FIGS. 15 and 16, the donor wafer is planarized until the upper surfaces of the structures 11′ are again at the same level with the template layer. The bonding layer 14 may remain on the template layer at this point, as shown in the drawing, or the bonding layer 14 may be removed by the planarization. The donor wafer is then again ready to undergo the steps shown in FIGS. 9 to 11. This can be repeated a number of times, until the high-quality material of the structures 11 is consumed.

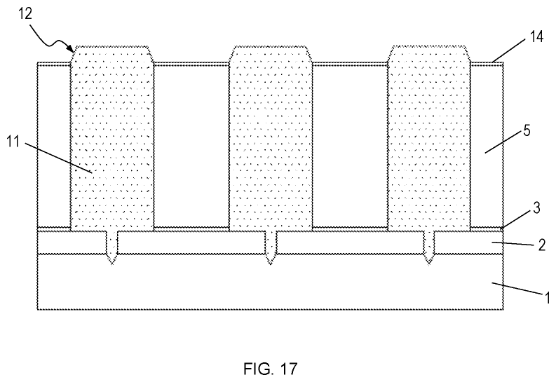

According to another example embodiment, the material is re-grown on the remaining bulk structures 11′ after the transfer of the stripes. This is illustrated in FIG. 17. The way in which the material grows is material-dependent and may be faceted so that the material grows along inclined surfaces, as shown. Before regrowth, a pretreatment may be performed. The pretreatment may include a baking step together with an in situ vapor phase etching step before growth to remove native oxides formed on the surface due to exposure to air and to smooth the surface before regrowth. Planarizing the donor before (e.g., prior to) regrowth is also possible, wherein the bonding layer 14 may be removed by the planarization. The regrowth again forms stripes 12, which can be transferred in the same way as described hereinabove.

Two recycling methods are thereby identified. The first method involves planarization followed by further recessing the template layer 2,3,5, and the second method involves regrowth of the material. The two recycling methods may be used alternatingly or in any given sequence of re-use cycles.

While some example embodiments have been illustrated and described in detail in the appended drawings and the foregoing description, such illustration and description are to be considered illustrative and not restrictive. Other variations to the disclosed example embodiments can be understood and effected in practicing the claims, from a study of the drawings, the disclosure, and the appended claims. The mere fact that certain measures or features are recited in mutually different dependent claims does not indicate that a combination of these measures or features cannot be used. Any reference signs in the claims should not be construed as limiting the scope.

What is claimed is:

1. A donor wafer for producing engineered semiconductor substrates, the donor wafer comprising:
a support substrate formed of a first crystalline semiconductor material;
a template layer on the support substrate, the template layer comprising a plurality of trenches extending through an entire thickness of the template layer; and
a plurality of structures disposed in the trenches and formed of a second crystalline semiconductor material,
wherein each structure of the plurality of structures comprises a planar bonding surface, and each planar bonding surface is coplanar,
wherein an upper surface of the template layer is recessed relative to each planar bonding surface such that stripe portions of each structure extends outward from the recessed upper surface of the template layer, and
wherein each structure of the plurality of structures comprises a release layer positioned to transfer at least an upper part of the stripe portions to a carrier substrate.

2. The donor wafer of claim 1, wherein each trench comprises a base portion and an upper portion, the upper portion is wider than the base portion.

3. The donor wafer of claim 2, wherein an aspect ratio of each of the base portion to the upper portion of each trench is equal to or greater than 2.

4. The donor wafer of claim 1, wherein a height of the stripe portions is between 10 nm and 1 μm.

5. The donor wafer of claim 1, wherein the first semiconductor material comprises silicon.

6. The donor wafer of claim 5, wherein the second semiconductor material comprises a group III-V semiconductor material or a group IV semiconductor material.

7. The donor wafer of claim 1, wherein a width of the stripe portions of the structures is between 0.5 μm and 20 μm.

8. The donor wafer of claim 1, wherein a threading dislocation density measured on the planar bonding surfaces of the structures is lower than 5E8 cm⁻².

9. The donor wafer of claim 1, wherein a threading dislocation density measured on the planar bonding surfaces of the structures is lower than 1E7 cm⁻².

10. A method for producing a donor wafer, the method comprising:
providing a support substrate formed of a first crystalline semiconductor material;
forming a template layer on the support substrate, wherein the template layer comprises a plurality of trenches extending through an entire thickness of the template layer, each trench of the plurality of trenches has a base portion and an upper portion, wherein an upper surface of the support substrate is exposed at a bottom of the base portion of each trench of the plurality of trenches, and the upper portion is wider than the base portion;
growing, by epitaxial growth, structures formed of a second crystalline semiconductor material upward from the bottom of each base portion of each trench of the plurality of trenches, the structures growing upward and outward of each base portion to be embedded in a respective upper portion of each trench, wherein a crystal orientation and a shape of the bottom of each base portion and an aspect ratio of each base portion is configured to provide aspect ratio trapping of threading dislocations in each base portion;
continuing the epitaxial growth until the structures extend outward from the upper portion of each trench;
performing planarization, thereby making upper surfaces of the structures and the template layer coplanar and forming coplanar bonding surfaces of the structures;
recessing the template layer relative to the structures to form stripe portions extending outward from a recessed upper surface of the template layer; and
implanting ions in the structures to form a release layer to transfer at least an upper part of the stripe portions to a carrier substrate.

11. The method of claim 10, further comprising forming a dielectric bonding layer conformally on a topography provided by the stripe portions and a surface of the recessed template layer.

12. The method of claim 11, wherein the implanting of the ions is performed after the forming of the dielectric bonding layer.

13. The method of claim 11, wherein the implanting of the ions is performed before the forming of the dielectric bonding layer.

14. A method for producing an engineered substrate, the method comprising:
providing a donor wafer comprising:
a support substrate formed of a first crystalline semiconductor material;
a template layer on the support substrate, the template layer comprising a plurality of trenches extending through an entire thickness of the template layer; and
a plurality of structures disposed in the trenches and formed of a second crystalline semiconductor material,
wherein each structure of the plurality of structures comprises a planar bonding surface, and each planar bonding surface is coplanar,
wherein an upper surface of the template layer is recessed relative to each planar bonding surface such that stripe portions of each structure extend outward from the recessed upper surface of the template layer, and
wherein each structure of the plurality of structures comprises a release layer positioned to transfer at least an upper part of the stripe portions to a carrier substrate;
forming, when the donor wafer does not comprise a dielectric bonding layer conformally formed on a topography provided by the stripe portions and the surface of the recessed template layer, producing the dielectric bonding layer on the topography;
bonding the donor wafer to a carrier substrate by bonding the dielectric bonding layer to the carrier substrate;
releasing the release layer to transfer at least an upper part of the stripe portions of the structures to the carrier substrate;
depositing a dielectric material on the carrier substrate, thereby filling spaces between transferred parts of the stripe portions; and
performing planarization to make a surface of the transferred parts of the stripe portions coplanar with the dielectric material, thereby obtaining the engineered substrate.

15. The method of claim 14, further comprising, after producing the engineered substrate,
preparing the donor wafer for reuse by:
planarizing the donor wafer to make upper surfaces of the structures and an upper surface of the template layer or a bonding layer coplanar.

16. The method of claim 15, further comprising recessing the template layer or the bonding layer relative to the structures to again form stripe portions of the structures extending outward from a recessed upper surface of the template layer or the bonding layer.

17. The method of claim 16, further comprising implanting ions in the structures to again form a release layer.

18. The method of claim 14, further comprising, after producing the engineered substrate, preparing the donor wafer for reuse by growing, by selective epitaxial growth, the second crystalline semiconductor material on released structures to again form stripe portions of the structures extending outward from the recessed upper surface of the template layer.

19. The method of claim 18, further comprising implanting ions in the structures to again form a release layer.
